(19) United States
(12) Patent Application Publication
(10) Pub. No.: US 2026/0047377 A1
(43) Pub. Date: Feb. 12, 2026

(54) SUBSTRATE PROCESSING METHOD AND SUBSTRATE PROCESSING APPARATUS

(71) Applicant: SCREEN Holdings Co., Ltd., Kyoto (JP)

(72) Inventors: Takashi IZUTA, Kyoto-shi, Kyoto (JP); Mitsutoshi SASAKI, Kyoto-shi, Kyoto (JP); Yusuke SEKI, Kyoto-shi, Kyoto (JP)

(21) Appl. No.: 19/284,904

(22) Filed: Jul. 30, 2025

(30) Foreign Application Priority Data
Aug. 7, 2024 (JP) 2024-130844

(51) Int. Cl. H01L 21/67; H01L 21/306

(52) U.S. Cl. CPC H01L 21/67086; H01L 21/30604

(57) ABSTRACT

A substrate processing apparatus according to the present invention includes a step (immersing step) of immersing a substrate array that is a horizontal arrangement of vertically oriented substrates in sulfuric acid, a step (elevating step) of elevating an entirety of the substrate array from the sulfuric acid, and a step (mist supplying step) of supplying mist of hydrogen peroxide solution to the substrate array having been elevated. With this configuration, only the liquid sulfuric acid film attached to the surface of the substrate is turned into SPM. In this manner, much less hydrogen peroxide solution is consumed, as compared with that in a conventional method.

This application claims priority to Japanese Patent Application No. 2024-130844 filed Aug. 7, 2024, the subject matter of which is incorporated herein by reference in entirety.

### BACKGROUND OF THE INVENTION

The present invention relates to a substrate processing method and a substrate processing apparatus for batch-processing a plurality of substrates at once, using sulfuric acid and hydrogen peroxide mixture (SPM).

### DESCRIPTION OF THE RELATED ART

JP 2010-103190 A describes a substrate processing apparatus for processing a substrate using a first treatment liquid containing sulfuric acid and a second treatment liquid containing hydrogen peroxide, the substrate processing apparatus including: a sulfuric-acid bath that stores the first treatment liquid in a high-temperature state; a substrate lifting mechanism that lifts and lowers the substrate with respect to the sulfuric-acid bath; and a mist feeding unit configured to supply mist of the second treatment liquid near the liquid surface of the first treatment liquid, when the substrate lifting mechanism elevates the substrate from the sulfuric-acid bath or is to immerse the substrate in the sulfuric-acid bath. With such a substrate processing apparatus, hydrogen peroxide can be supplied to a substrate with the sulfuric acid attached on the surface.

### LIST OF DOCUMENTS

JP 2010-103190 A

Such a configuration, however, fails to keep the hydrogen peroxide solution consumption used in the SPM treatment sufficiently low. In the method used in conventional SPM treatment, substrates are immersed in an SPM bath containing a mixture of hydrogen peroxide solution and sulfuric acid. With this method, it is necessary to keep supplying the hydrogen peroxide solution and sulfuric acid to the SPM bath, in order to achieve a desirable effect of the chemical treatment on the substrates. In this regard, the method according to JP 2010-103190 A has succeeded in suppressing the consumption of hydrogen peroxide solution to some degree. This is because, by supplying hydrogen peroxide solution as mist from above the sulfuric-acid bath, SPM is formulated only on the liquid surface of the sulfuric acid. In other words, the method according to JP 2010-103190 A can reduce the consumption of hydrogen peroxide solution, in comparison with the configuration in which the SPM is formulated in the entire sulfuric-acid bath.

However, the method according to JP 2010-103190 A is not sufficient in the effects of reducing the consumptions of hydrogen peroxide solution and sulfuric acid.

The present invention has been made in view of such a circumstance, and an object of the present invention is to provide a substrate processing method and a substrate processing apparatus capable of suppressing the consumption of a chemical liquid.

### SUMMARY OF THE INVENTION

In order to address the issue described above, the present invention has a configuration such as that follows. That is, a substrate processing method according to the present invention includes:
an immersing step of immersing a substrate array that is a horizontal arrangement of vertically oriented substrates in sulfuric acid;
a elevating step of elevating an entirety of the substrate array from the sulfuric acid; and
a mist supplying step of supplying mist of hydrogen peroxide solution to the substrate array having been elevated.

[Operations and Effects] The substrate processing method according to the present invention includes: an immersing step of immersing a substrate array that is a horizontal arrangement of vertically oriented substrates in sulfuric acid; a elevating step of elevating an entirety of the substrate array from the sulfuric acid; and a mist supplying step of supplying mist of hydrogen peroxide solution to the substrate array having been elevated. With this configuration, only the liquid sulfuric acid film attached to the surface of the substrate is turned into SPM. As a result, with the chemical treatment according to the present invention, the consumed amount of hydrogen peroxide solution is reduced significantly, compared with that consumed in a conventional counterpart.

More preferably, the substrate processing method described above further includes a re-immersing step of re-immersing the substrate array in the sulfuric acid, after the mist supplying step.

[Operations and Effects] The configuration described above further includes a re-immersing step of re-immersing the substrate array in the sulfuric acid, after the mist supplying step. With this configuration, the reliability of substrate processing for substrates is improved.

More preferably, in the substrate processing method, in the mist supplying step, the substrate array is reciprocated up and down in a space above a liquid surface of the sulfuric acid.

[Operations and Effects] With the configuration described above, in the mist supplying step, the substrate array is reciprocated up and down in a space above the liquid surface of the sulfuric acid. With this configuration, the entire area of the substrates can be thoroughly subjected to the hydrogen peroxide solution.

More preferably, in the substrate processing method described above,
the substrate array has a resist layer, and
the sulfuric acid in the immersing step is set to a temperature higher than a target temperature that is suitable for removing the resist layer.

[Operations and Effects] With the configuration described above, the sulfuric acid in the immersing step is set to a temperature higher than a target temperature that is suitable for removing the resist layer. With this configuration, the substrate processing in the mist supplying step can be carried out at an appropriate temperature. In the mist supplying step, the substrates are cooled by the mist of hydrogen peroxide solution. With this configuration, because the substrates are heated to the higher temperature in the immersing step, by allowing the mist of hydrogen peroxide solution to cool the substrates, the temperature of the substrates is lowered to a temperature suitable for the removal of the resist layer.

Note that the present specification also discloses the following substrate processing apparatus.

That is, a substrate processing apparatus according to the present invention includes:
a sulfuric-acid bath capable of holding sulfuric acid;
a lifter holds a substrate array that is a horizontal arrangement of vertically oriented substrates, and capable of switching the substrate array between a standby state in which the substrate array is positioned above a liquid surface of the sulfuric-acid bath and an immersed state in which the substrate array is positioned below the liquid surface;
a mist feeding unit configured to supply mist of hydrogen peroxide solution to the substrate array; and
a control unit configured to control the lifter and the mist feeding unit,
in which the control unit
controls the lifter to switch the substrate array in the standby state to the immersed state,
controls the lifter to switch the substrate array in the immersed state to the standby state so that an entirety of the substrate array is elevated from sulfuric acid, and
controls the mist feeding unit to supply the mist of hydrogen peroxide solution to the substrate array having been elevated from the sulfuric acid.

[Operations and Effects] The substrate processing apparatus according to the present invention includes a control unit configured to control the lifter and the mist feeding unit, and the control unit controls the lifter to switch the substrate array in the standby state to the immersed state, controls the lifter to switch the substrate array in the immersed state to the standby state so that an entirety of the substrate array is elevated from sulfuric acid, and controls the mist feeding unit to supply the mist of hydrogen peroxide solution to the substrate array having been elevated from the sulfuric acid. With this configuration, it is possible to provide a substrate processing apparatus achieving the above-described effects according to the present invention.

Furthermore, more preferably, in the substrate processing apparatus described above, the control unit controls the lifter to switch the substrate array in the standby state to the immersed state, so that the substrates supplied with the mist of hydrogen peroxide solution are immersed in the sulfuric acid.

[Operations and Effects] In the configuration described above, the lifter is controlled to switch the substrate array in the standby state to the immersed state, so that the substrates supplied with the mist of hydrogen peroxide solution is immersed in the sulfuric acid. With this configuration, the re-immersing step described above can be implemented reliably.

Furthermore, more preferably, in the substrate processing apparatus described above,
the mist feeding unit includes a nozzle head provided at a tip of a nozzle for supplying the hydrogen peroxide solution,
the substrate processing apparatus includes
a first nozzle head array including a plurality of the nozzle heads that are arranged along a direction in which the substrates are arranged, with a predetermined distance between the nozzle heads, and
a second nozzle head array including a plurality of the nozzle heads that are arranged along the direction in which the substrates are arranged, with a predetermined distance between the nozzle heads, with the substrate array being interposed between the first nozzle head array and the second nozzle head array in a direction orthogonal to the direction in which the substrates are arranged, and
the nozzle heads included in the second nozzle head array are provided at positions offset from the respective nozzle heads included in the first nozzle head array, by a half the predetermined distance in the direction in which the substrates are arranged.

[Operations and Effects] The configuration described above includes: a first nozzle head array including a plurality of the nozzle heads that are arranged along a direction in which the substrates are arranged, with a predetermined distance between the nozzle heads; and a second nozzle head array including a plurality of the nozzle heads that are arranged along the direction in which the substrates are arranged, with a predetermined distance between the nozzle heads, with the substrate array being interposed between the first nozzle head array and the second nozzle head array in a direction orthogonal to the direction in which the substrates are arranged, and the nozzle heads included in the second nozzle head array are provided at positions offset from the respective nozzle heads included in the first nozzle head array, by a half the predetermined distance in the direction in which the substrates are arranged. With this configuration, the mist of hydrogen peroxide solution can be evenly supplied to the substrate array.

Furthermore, more preferably, the substrate processing apparatus described above further includes:
a cover that is displaceable between a closed state for covering a top of the sulfuric-acid bath, and an open state for having moved to a position evacuated from above the sulfuric-acid bath; and
a cover driving mechanism configured to operate the cover,
in which the control unit controls the cover driving mechanism to switch the cover in the open state to the closed state after elevating the substrate array from the sulfuric-acid bath and before supplying the mist of hydrogen peroxide solution.

[Operations and Effects] The configuration described above includes: a cover that is displaceable between a closed state for covering a top of the sulfuric-acid bath, and an open state for having moved to a position evacuated from above the sulfuric-acid bath; and a cover driving mechanism configured to operate the cover, and the control unit controls the cover driving mechanism to switch the cover in the open state to the closed state after elevating the substrate array from the sulfuric-acid bath and before supplying the mist of hydrogen peroxide solution. With this configuration, the cover can isolate the space for the substrate processing using the sulfuric acid, from the space for the substrate processing using the hydrogen peroxide. As a result, it is possible to inhibit the mist of hydrogen peroxide solution from becoming mixed to the sulfuric acid, reliably.

Furthermore, more preferably, the substrate processing apparatus described above further includes a discharge port for discharging the hydrogen peroxide solution having been attached to the cover.

[Operations and Effects] The configuration described above includes a discharge port for discharging the hydrogen peroxide solution having been attached to the cover. With this configuration, even when the cover is brought to the open state, the hydrogen peroxide solution having been attached to the cover does not reach the sulfuric-acid bath. Moreover, with this configuration, because the hydrogen peroxide solution is collected, the hydrogen peroxide solution to be sprayed as mist can be easily reused.

According to the present invention, it is possible to provide a substrate processing method and a substrate processing apparatus capable of suppressing the consumption of a chemical liquid.

### BRIEF DESCRIPTION OF THE DRAWINGS

FIG. 1 is a plan view for explaining a configuration of the entire substrate processing apparatus according to an embodiment;

FIG. 2 is a side view for explaining a configuration of a carrier according to the embodiment;

FIG. 3 is a perspective view illustrating a transfer block according to the embodiment;

FIG. 4 is a cross-sectional view for explaining a batch processing unit according to the embodiment;

FIG. 5 is a flowchart for explaining an operation of the batch processing unit according to the embodiment;

FIG. 6 is a cross-sectional view for explaining the operation of the batch processing unit according to the embodiment;

FIG. 7 is a cross-sectional view for explaining the operation of the batch processing unit according to the embodiment;

FIG. 8 is a cross-sectional view for explaining the operation of the batch processing unit according to the embodiment;

FIG. 9 is a plan view for explaining a chemical liquid treatment according to the embodiment;

FIG. 10 is a cross-sectional view for explaining the operation of the batch processing unit according to the embodiment;

FIG. 11 is a plan view for explaining a chemical liquid treatment according to the embodiment;

FIG. 12 is a cross-sectional view for explaining the operation of the batch processing unit according to the embodiment;

FIG. 13 is a cross-sectional view for explaining the operation of the batch processing unit according to the embodiment;

FIG. 14 is a cross-sectional view for explaining the operation of the batch processing unit according to the embodiment;

FIG. 15 is a cross-sectional view for explaining the operation of the batch processing unit according to the embodiment;

FIG. 16 is a cross-sectional view for explaining the operation of the batch processing unit according to the embodiment;

FIG. 17 is a cross-sectional view for explaining the operation of the batch processing unit according to the embodiment;

FIG. 18 is a flowchart for explaining the sequence of substrate processing according to the embodiment;

FIG. 19 is a cross-sectional view for explaining a modification of the present invention;

FIG. 20 is a plan view for explaining a modification of the present invention; and

FIG. 21 is a flowchart for explaining a modification of the present invention.

### DESCRIPTION OF THE PREFERRED EMBODIMENTS

Preferred embodiments of the present invention will now be described with reference to drawings. A substrate processing apparatus according to the present invention is a configuration capable of subjecting a plurality of vertically oriented substrates to a sulfuric-acid and hydrogen-peroxide-mixture (SPM) treatment all at once. With the SPM treatment according to the present invention, the residue of photoresist remaining on the substrate can be removed. The photoresist residue is an example of a resist layer according to the present invention. Specifically, the SPM treatment according to the present invention is a chemical treatment using a liquid mixture of sulfuric acid and hydrogen peroxide solution.

### EMBODIMENT

### <1. Overall Configuration>

A substrate processing apparatus 1 according to the present invention is configured to perform batch processing, and includes a housing 1A in which blocks of the substrate processing apparatus 1 are housed. The housing 1A has a loading port 9 projecting from a first wall surface that is orthogonal to a Y direction extending in a direction from a processing block 6 toward a transfer block 5. On the loading port 9, it is possible to place a carrier C for storing a substrate array including horizontally oriented substrates W arranged along the vertical direction at a specific pitch.

In the description herein, for the sake of convenience, the direction along which a stocker block 3, a transfer block 5, and the processing block 6 are arranged in the substrate processing apparatus 1 will be referred to as a “front-back direction X”. The front-back direction X extends horizontally. In the front-back direction X, the direction from the transfer block 5 toward the stocker block 3 in the substrate processing apparatus 1 will be referred to as “frontward”. The direction opposite to the frontward direction will be referred to as “rearward”. The direction extending horizontally and orthogonally to the front-back direction X will be referred to as “width direction Y”. One of the “width direction Y” will be referred to as “rightward” for the convenience of description, and the other will be referred to as “leftward” for the convenience of description. The direction (height direction) orthogonal to the front-back direction X as well as to the width direction Y will be referred to as a “vertical direction Z” for the convenience of description. In each of the drawings, front, rear, right, left, top, and bottom are indicated as appropriate, for the reference.

### <2. Stocker Block>

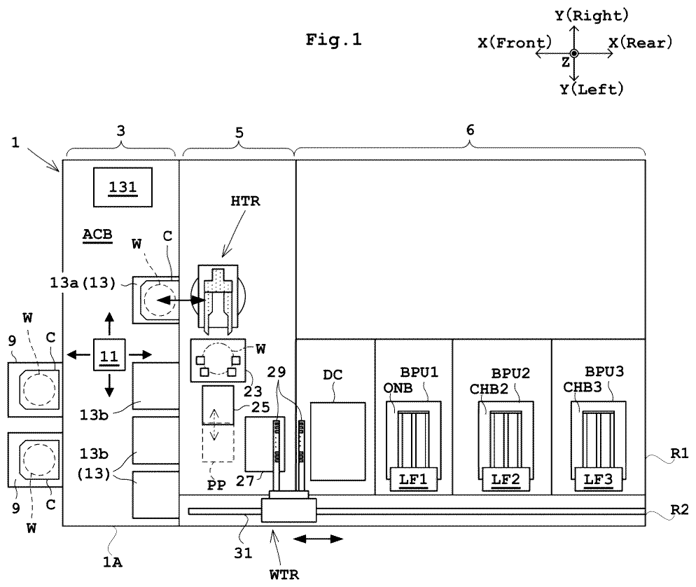

As illustrated in FIG. 1, the stocker block 3 includes loading ports 9 each of which is an entrance via which a carrier C storing therein a plurality of horizontally oriented substrates W arranged along the vertical direction at predetermined intervals is carried into the block. The loading ports 9 is a configuration projecting from the outer wall of the stocker block 3 that extends in the width direction (Y direction).

In one carrier C, a plurality of (e.g., twenty five) horizontally oriented substrates W are stored, with constant intervals therebetween, as a stack. The carrier C storing therein unprocessed substrates W, which are to be carried into the substrate processing apparatus 1, is at first placed on the loading port 9.

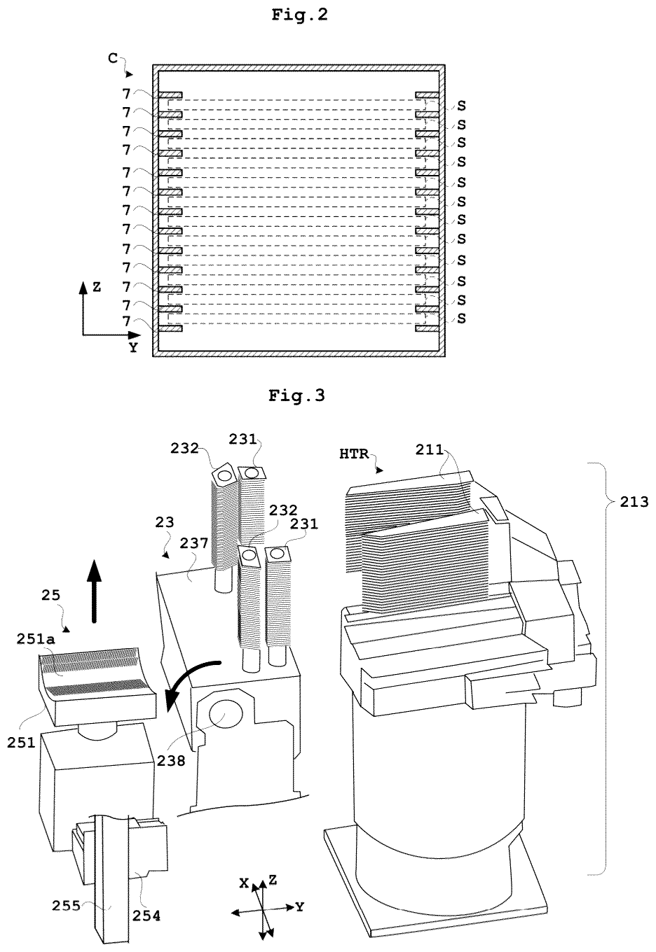

FIG. 2 illustrates a configuration of the carrier C according to the present invention. The carrier C has a plurality of slots S extending in the horizontal direction for holding the substrates W in such a manner that the surfaces thereof are spaced apart from each other. The slots S are arranged at a specific pitch (for example, 10 mm) along the vertical direction, and each of the slots S stores one substrate W. Twenty five slots S are provided to one carrier C. Therefore, in the carrier C, twenty five substrates W are arranged at a specific pitch along the vertical direction. At the positions partitioning the slots S, holder plates 7 are provided, respectively, and each of the holder plates 7 supports two ends of the substrate W, with another holder plate 7 paired therewith. Therefore, arrays of the holder plates 7 are provided to the one side surface of the carrier C and the surface in parallel with the one side surface, respectively. One example of the carrier C is a sealed front opening unified pod (FOUP). In the present invention, an open container may also be used as the carrier C.

An internal structure of the stocker block 3 will now be described. The stocker block 3 includes a transport storage area ACB where the carriers C are stocked and managed. The transport storage area ACB is provided with a carrier transport mechanism 11 for transporting a carrier C, and a shelf 13 on which a carrier C is placed. The stocker block 3 can stock one or more carriers C.

The stocker block 3 has a plurality of shelves 13 where the carriers Care placed. The shelves 13 are provided to a partitioning wall between the stocker block 3 and the transfer block 5. The shelves 13 includes a stocker shelf 13b for simply placing the carrier C temporarily, and a carrier shelf 13a accessed by a first handling robot HTR provided to the transfer block 5 so as to take out a substrate.

The carrier shelf 13a is a configuration on which the carrier C can be placed. The carrier shelf 13a is a configuration for placing a carrier C from which a substrate W is to be taken out. In this embodiment, one carrier shelf 13a is provided, but it is also possible to provide a plurality of the carrier shelves 13a. The carrier transport mechanism 11 collects a carrier C, storing therein unprocessed substrates W, from the loading port 9, and places the carrier C on the carrier shelf 13a from which the substrates are to be taken out. At this time, the carrier transport mechanism 11 can also place the carrier C on the stocker shelf 13b temporarily before placing the carrier C on the carrier shelf 13a. The stocker block 3 has one or more carrier shelves 13a.

The carrier shelf 13a also has a configuration for placing an empty carrier C to which processed substrates W are to be stored. Processed substrates W are stored in the carrier C kept standby on the carrier shelf 13a. The carrier transport mechanism 11 collects the carrier C storing the processed substrates W from the carrier shelf 13a, and transports the carrier C to the loading port 9. In the process of transporting the carrier C to the loading port 9, the carrier transport mechanism 11 may temporarily place the carrier C on the stocker shelf 13b.

### <3. Transfer Block>

The transfer block 5 is positioned adjacently to the carrier shelf 13a. The transfer block 5 is disposed adjacently on the rear side of the stocker block 3. The transfer block 5 includes the handling robot HTR capable of accessing a carrier C placed on the carrier shelf 13a from which a substrate is taken out, an HVC orientation converting unit 23 that changes the orientation of a plurality of substrates W, from the horizontal orientation to the vertical orientation at once, and a pusher mechanism 25. The HVC orientation converting unit 23 converts the orientation of a set of a plurality of substrates W from the horizontal orientation to the vertical orientation at once. In the transfer block 5, a substrate passing position PP is set as a position at which the plurality of substrates W are passed to a substrate transport mechanism WTR, which is provided to a batch transport region R2.

As illustrated in FIG. 3, the handling robot HTR, the HVC orientation converting unit 23, and the pusher mechanism 25 are arranged along the Y direction, in the order listed herein. The handling robot HTR includes a plurality of hands 211 capable of gripping horizontally oriented substrates W, respectively. Each one of the hands 211 is capable of gripping one substrate W. On the handling robot HTR, the plurality of hands 211 are arranged along the vertical direction. By causing the plurality of hands 211 to grip the respective substrates, the handling robot HTR can transport a plurality of substrates W at once. An actuating support mechanism 213 is a mechanism of the handling robot HTR, and is a configuration for rotating the hands 211 about the vertical axis, moving the hands 211 up and down, advancing and retracting the hands 211 in the front-back direction X, and moving the hands 211 laterally in the left-right direction Y.

The handling robot HTR is provided with twenty five hands 211. The handling robot HTR thus transports twenty five substrates stored in a carrier C, all at once.

The HVC orientation converting unit 23 is a configuration for converting the orientation of the substrates W having been taken out by the handling robot HTR from the carrier C, from the horizontal orientation to the vertical orientation. The HVC orientation converting unit 23 includes a pair of placing rods 231 and a pair of clamping rods 232 extending in the vertical direction (Z direction). A support base 237 has a support surface extending along an XY plane, and supporting the placing rods 231 and the clamping rods 232. A rotation driving mechanism 238 is a configuration for rotating the entire support base 237, including the placing rods 231 and the clamping rods 232, by 90°. As a result of this rotation, the placing rods 231 and the clamping rods 232 come to extend in the left-right direction (Y direction).

The pusher mechanism 25 includes a pusher 251 capable of aligning the vertically oriented substrates W in the horizontal direction. The pusher 251 is a half-pipe pusher having a shape that follows the bottom curve of the substrates W. A U groove 251a forming the half pipe of the pusher 251 extends in the left-right direction Y, in the initial state. The pusher 251 in the initial state can receive the substrates W from the HVC orientation converting unit 23.

A pusher shifting mechanism 254 can cause the pusher 251 in the initial state to move back and forth in the left-right direction Y. The pusher shifting mechanism 254 can move the pusher 251 closer to the HVC orientation converting unit 23, or move the pusher 251 closer to the substrate transport mechanism WTR.

A pusher lifting mechanism 255 can lift the pusher 251 at an initial position to a higher position. The pusher lifting mechanism 255 can also bring the pusher 251 at the higher position back to the initial position.

Transportation of the horizontally oriented substrates W, having been picked up from the carrier C by the handling robot HTR, onto the pusher 251 will now be described. To begin with, the handling robot HTR directs the hands 211 forward, and picks up an array of horizontally oriented substrates from the carrier C, all at once. The handling robot HTR then rotates the hands 211 about a vertically extending rotation axis, and directs the hands 211 toward the HVC orientation converting unit 23, as illustrated in FIG. 3. In FIG. 3, the substrates W held by the hands 211 are not illustrated.

The hands 211 then pass the substrate array onto the HVC orientation converting unit 23. At this time, the substrates W are held by the pair of placing rods 231.

The HVC orientation converting unit 23 having received the substrate array then converts the orientation of the substrates W included in the substrate array from the horizontal orientation to the vertical orientation, by causing the rotation driving mechanism 238 to operate, as indicated by the arrow in FIG. 3. As a result, the horizontal oriented substrates W having been arranged along the vertical direction are converted into the vertical orientation, in a manner arranged along the left-right direction Y (horizontal direction). At this time, the substrates W are released from the pair of placing rods 231, and become supported on the pair of clamping rods 232.

Prior to this rotating operation of the HVC orientation converting unit 23, the pusher mechanism 25 moves the pusher 251 downward, as illustrated in FIG. 3, and waits for the arrival of the substrate array. The pusher mechanism 25 then raises the pusher 251 toward the substrates W supported by the clamping rods 232, as indicated by the arrow in FIG. 3. The substrates W are then pushed up by the pusher 251, separate from the clamping rods 232, and are eventually held only by the pusher 251. In this manner, the pusher mechanism 25 receives the substrates W from the HVC orientation converting unit 23.

By repeating this process of receiving the substrate array twice, the pusher mechanism 25 can form a lot including fifty substrates arranged along the horizontal direction. One lot includes substrates W corresponding to two carriers C illustrated in FIG. 2, and the substrates W in the lot are arranged at a half pitch (5 mm) of the pitch of the substrates W in the carrier C. Furthermore, between these first and the second substrate array receiving operation, the substrate processing apparatus according to the present invention may also perform an additional operation of rotating the pusher 251 by 180° about a vertical axis. The lot is one kind of a substrate array according to the present invention.

The transfer block 5 includes, as a part capable of holding the substrate array other than the pusher 251, a substrate array support 27. The substrate array support 27 serves as a lot holding unit where the substrate array is temporarily kept waiting when the substrate arrays become congested between the transfer block 5 and the processing block 6.

### <4. Processing Block>

A configuration of the processing block 6, having been explained with reference to FIG. 1, will now be described. The processing block 6 is positioned adjacently to the transfer block 5. In the processing block 6, batch processing of the substrate array described above is performed. The processing block 6 includes a batch processing region R1 and a batch transport region R2 that are arranged along the width direction (Y direction). Each of these regions extends in the front-back direction (X direction). More specifically, the batch processing region R1 is positioned inside the processing block 6. The batch transport region R2 is positioned adjacently to the batch processing region R1, and is positioned on the leftmost side of the processing block 6.

The batch processing region R1 in the processing block 6 is a rectangular region stretching in the front-back direction (X direction). One end (front side) of the batch processing region R1 is positioned adjacently to the transfer block 5. The other end of the batch processing region R1 extends in a direction separating from the transfer block 5 (toward the rear side). To transport a substrate array from the transfer block 5 to the processing block 6, the substrate transport mechanism WTR included in the processing block 6 is used.

The substrate transport mechanism WTR transports a plurality of vertically oriented substrates W all at once, between the transfer block 5, each of batch processing units BPU1 to BPU3, and a batch drying chamber DC. The substrate transport mechanism WTR can hold a substrate array including vertically oriented substrates W. For example, the substrate transport mechanism WTR can deliver a substrate array received from the pusher 251 in the transfer block 5 to a lifter in corresponding one of the batch processing units. The substrate transport mechanism WTR can access any of the pusher 251 in the transfer block 5, the substrate array support 27, the lifters in the processing block 6, and the batch drying chamber DC.

The batch processing region R1 includes a batch processing unit where batch processing is carried out. Specifically, the batch processing region R1 has the batch drying chamber DC, in which a plurality of substrates W are dried at once, and a plurality of batch processing units BPU1 to BPU3 in which a plurality of substrates W are immersed, and that are arranged along the direction in which the batch processing region R1 extends. In each of the batch processing units BPU1 to BPU3, a plurality of vertically oriented substrates W are immersed at once. The layout of the batch drying chamber DC and the batch processing units BPU1 to BPU3 will now be described specifically. The batch drying chamber DC is positioned adjacently on the rear side of the transfer block 5. The first batch processing unit BPU1 is positioned adjacently on the rear side of the batch drying chamber DC. The second batch processing unit BPU2 is positioned adjacently on the rear side of the first batch processing unit BPU1. The third batch processing unit BPU3 is positioned adjacently on the rear side of the second batch processing unit BPU2. In this manner, the batch drying chamber DC, the first batch processing unit BPU1, the second batch processing unit BPU2, and the third batch processing unit BPU3 are arranged, in the order listed herein, along the direction separating from the transfer block 5.

Each of the batch processing units BPU1 to BPU3 includes a batch treatment bath capable of holding a liquid. The batch treatment bath is a liquid bath for holding sulfuric acid or pure water. Batch treatment baths for holding sulfuric acid will be referred to as sulfuric-acid baths CHB2 to CHB3, and a batch treatment bath for holding pure water (hot pure water) will be referred to as a batch rinsing treatment bath ONB. The sulfuric-acid baths CHB2 to CHB3 are particularly configured to hold hot sulfuric acid.

### <5. Configuration of Batch Processing Unit>

A configuration of the batch processing unit according to this embodiment will be explained using the second batch processing unit BPU2 as an example. Specifically, the second batch processing unit BPU2 includes a sulfuric-acid bath CHB2 storing therein sulfuric acid, and a lifter LF2 configured to move a substrate array up and down between a substrate passing position and an immersing position (see FIG. 1). The substrate passing position is a position accessible by the substrate transport mechanism WTR and set above the sulfuric-acid bath CHB2, and the immersing position is a position where the entire substrate array can be immersed in the sulfuric acid, and set inside the sulfuric-acid bath CHB2. The second batch processing unit BPU2 subjects a substrate array to SPM treatment.

The lifter LF2 can hold a substrate array. The lifter LF2 holds a substrate array that are vertically oriented substrates arranged along the horizontal direction, and can switch the state of the substrate array between a standby state in which the substrate array is above the liquid surface of the sulfuric-acid bath CHB2 and an immersed state in which the substrate array is positioned below the liquid surface. The lifters provided to the other treatment baths can also hold the substrate arrays in the same manner as the lifter LF2. The batch drying chamber DC is capable of housing a substrate array.

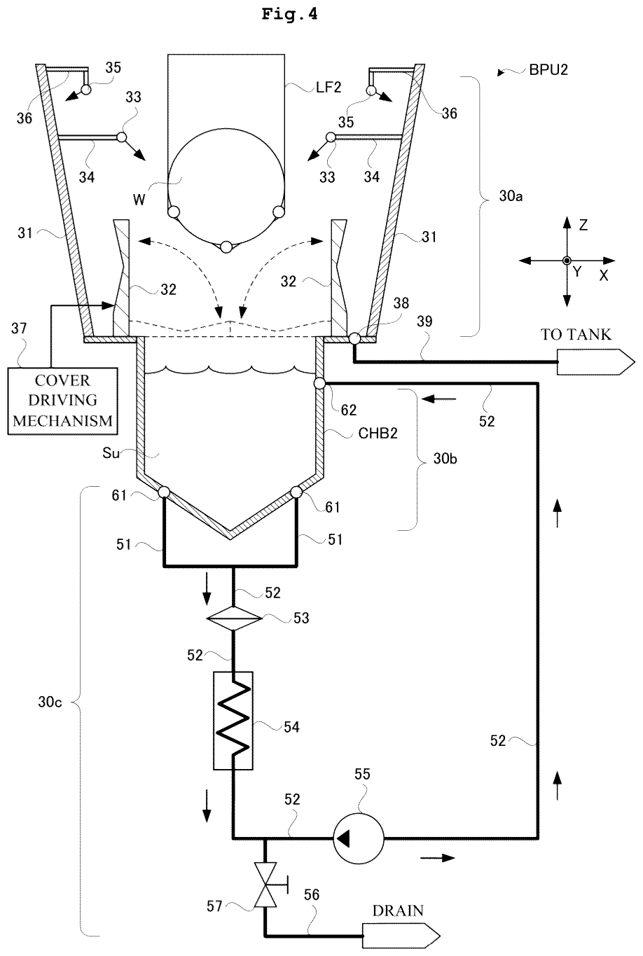

FIG. 4 illustrates a specific configuration of the batch processing unit BPU2. That is, the batch processing unit BPU2 includes a mist treatment region 30a related to treatment with mist of hydrogen peroxide solution, and an immersing treatment region 30b in which the substrate array is immersed in hot sulfuric acid. The mist treatment region 30a is set above the immersing treatment region 30b. The lifter LF2 can move a substrate array between the mist treatment region 30a and the immersing treatment region 30b, by moving upward and downward.

As illustrated in FIG. 4, the mist treatment region 30a has a side wall 31 forming a space where the lifter LF2 is housed. The side wall 31 is tapered in such a manner that the space becomes narrower toward the bottom. With this, the moisture attached on the inner side of the side wall 31 trickles along the side wall 31 and becomes gathered at the bottom of the mist treatment region 30a. Therefore, this configuration is advantageous in collecting the moisture in the mist treatment region 30a.

A pair of covers 32 capable of separating the mist treatment region 30a from the immersing treatment region 30b is provided at the bottom of the mist treatment region 30a. By rotating the pair of covers 32 synchronously, the pair of covers 32 can be switched between an open state allowing the lifter LF2 in the mist treatment region 30a to pass to the immersing treatment region 30b, and a closed state prohibiting the passage of the lifter LF2. The pair of covers 32 is waterproof. Therefore, with the pair of covers 32 in the closed state, the moisture in the mist treatment region 30a does not leak into the immersing treatment region 30b. That is, the covers 32 can be displaced between the closed state in which covering is provided above the sulfuric-acid bath CHB2 and the open state in which the covers are moved to a position evacuated from above the sulfuric-acid bath CHB2. The covers 32 are enabled to be in the closed state when the lifter LF2 is in the mist treatment region 30a, as well as when the lifter LF2 is in the immersing treatment region 30b. In any case, when the covers 32 are in the closed state, liquid such as hydrogen peroxide solution or pure water in the mist treatment region 30a cannot pass through the covers 32, so that the liquid is prohibited from reaching the sulfuric-acid bath CHB2.

A cover driving mechanism 37 rotates the pair of covers 32 synchronously to switch the states of the covers 32.

In the mist treatment region 30a, a plurality of nozzle heads 33 for forming mist of hydrogen peroxide solution are provided. The nozzle heads 33 are provided on the left and right sides of the substrate array, and sprays the mist of hydrogen peroxide solution diagonally downward. The sprayed mist of hydrogen peroxide solution is directed to the substrate array, and a part thereof becomes attached to the surfaces of the substrates W in the substrate array. Each of the nozzle heads 33 is provided at the tip of a feed pipe 34 extending in the horizontal direction. The nozzle heads 33 are configured to supply the hydrogen peroxide solution onto the substrate array, and corresponds to a mist feeding unit according to the present invention. The feed pipes 34 are provided in a manner projecting from the side wall 31 toward the lifter LF2.

Shower heads 35, by contrast, are capable of spraying pure water, and are provided above the nozzle heads 33. The shower heads 35 are provided on the left and right sides on the side wall 31, and spray pure water toward the side wall 31. The pure water sprayed from the shower heads 35 trickles along the side wall 31, and reaches the bottom of the mist treatment region 30a. At this time, because the cover 32 are in the closed state, the pure water does not reach the immersing treatment region 30b.

Each of the shower heads 35 is provided to the tip of a feed pipe 36 extending in the horizontal direction. The feed pipe 36 is provided to the side wall 31 in a manner projecting toward the lifter LF2.

A discharge port 38 through which collected liquid is discharged is provided to the bottom of the mist treatment region 30a. The discharge port 38 is connected to a tank that mainly stores hydrogen peroxide solution. This tank serves as a supply source for supplying hydrogen peroxide solution to the nozzle heads 33. The hydrogen peroxide solution stored in the tank therefore passes through the feed pipes 34, the nozzle heads 33, and the discharge port 38, and goes back to the tank again. By allowing the hydrogen peroxide solution to circulate, the amount of hydrogen peroxide solution consumption can be reduced. A drainage line 39 is a configuration for connecting the discharge port 38 to the tank.

The discharge port 38 located on the bottom of the mist treatment region 30a is a configuration for discharging the hydrogen peroxide solution attached to the surfaces of the pair of covers 32, for example, to the outside of the mist treatment region 30a.

The immersing treatment region 30b will now be described. The immersing treatment region 30b mainly includes the sulfuric-acid bath CHB2. Hot sulfuric acid Su is kept in the sulfuric-acid bath CHB2. The sulfuric-acid bath CHB2 has an opening on the top, and can receive the lifter LF2 having passed through the covers 32 that are in the open state. A plurality of liquid drainage ports 61 are provided to the bottom of the sulfuric-acid bath CHB2, and the liquid drainage ports 61 are connected to a circulation system 30c, which will be described later. To an upper part of the sulfuric-acid bath CHB2, a liquid supply port 62 is provided, and this liquid supply port 62 is also connected to the circulation system 30c, which will be described later.

The hot sulfuric acid Su in the sulfuric-acid bath CHB2 is heated by passing through the circulation system 30c that is provided outside the sulfuric-acid bath CHB2. In this manner, the hot sulfuric acid Su is kept at a constant temperature. Specifically, the temperature of the hot sulfuric acid Su is set slightly higher than the temperature suitable for the chemical reaction in the mist treatment region 30a. That is, the substrate array in the mist treatment region 30a is heated to a slightly higher temperature, and then cooled slightly by the mist of hydrogen peroxide solution to a temperature suitable for the chemical reaction. The chemical reaction herein is specifically a reaction for removing the resist layer with Caro's acid.

A specific configuration of the circulation system 30c will now be described. The circulation system 30c includes a feed line 51 provided to each of the liquid drainage ports 61, and a main line 52 communicating with the feed lines 51. The main line 52 is configured to circulate the sulfuric acid collected through the plurality of feed lines 51. The main line 52 is in communication with the liquid supply port 62. The main line 52 is thus configured to circulate the sulfuric acid incoming from the feed lines 51 to the liquid supply port 62, so that the sulfuric acid is discharged into the sulfuric-acid bath CHB2.

Various components are provided along the main line 52. Specifically, the main line 52 is provided with a filter 53, a heater 54, and a pump 55, from the upstream side to the downstream side thereof.

The filter 53 is provided for the purpose of protecting the heater 54 that is on the downstream side. The filter 53 is configured to prevent passage of solids attached to the substrate array in the sulfuric-acid bath CHB2 into the heater 54. An example of the solid collected by the filter 53 is resist layer residues removed from the substrate array.

The heater 54 includes a thermometer, and monitors the temperature of sulfuric acid passing through the heater 54. When it is determined that the temperature of sulfuric acid is low, the heater 54 starts heating the sulfuric acid. When the temperature of sulfuric acid increases and reaches a predetermined temperature, the heater 54 stops heating the sulfuric acid. In this manner, the heater 54 manages the temperature of the sulfuric acid through feedback control. The thermometer used by the heater 54 in the temperature management may also be provided to any position on one of the sulfuric-acid bath CHB2 and the circulation system 30c, as well as on the heater 54.

The pump 55 is a driving unit that creates a flow of sulfuric acid circulating through the main line 52. The pump 55 receives the sulfuric acid flowing out of the heater 54, and sends the sulfuric acid into the liquid supply port 62 on the sulfuric-acid bath CHB2.

The main line 52 has a branch line 56 between the heater 54 and the pump 55. The branch line 56 is connected to a drain, which is used when the sulfuric acid is drained from the sulfuric-acid bath CHB2. A valve 57 can control to pass or not to pass the sulfuric acid to the branch line 56. During the substrate treatment, the valve 57 is kept in the closed state. The valve 57 is brought to the open state when the maintenance of the sulfuric-acid bath CHB2 is to be carried out.

As described above, the circulation system 30c receives the sulfuric acid the temperature of which has been lowered by the entry of the substrate array, through the liquid drainage ports 61, and passes the sulfuric acid through the filter 53. The sulfuric acid having passed through the filter 53 is heated by the heater 54 as appropriate, and reaches the pump 55. The pump 55 receives the heated sulfuric acid, and sends the sulfuric acid to the liquid supply port 62. The heated sulfuric acid flows through the liquid supply port 62 into the sulfuric-acid bath CHB2. The hot sulfuric acid Su in the sulfuric-acid bath CHB2 according to this example thus waits for the arrival of a substrate array, while having the temperature thereof kept constant, in the manner described above.

The sulfuric acid in the sulfuric-acid bath CHB2 is kept at a temperature (e.g., 110° C. to 140° C.) higher than a target temperature (e.g., 110° C.) suitable for the SPM treatment for removing the resist layer on the substrates W. This is a measure for the reduction in the temperature of the substrate W, by being supplied with the mist of hydrogen peroxide solution in the SPM treatment. The substrates W having been heated by the sulfuric acid are thus cooled by the mist of hydrogen peroxide solution to the target temperature, and is subjected to the SPM treatment.

The sulfuric-acid bath CHB2 is provided with the lifter LF2 for carrying the substrate array up and down. The lifter LF2 moves up and down in the vertical direction (Z direction). Specifically, the lifter LF2 moves up and down between an immersing position corresponding to a position inside the sulfuric-acid bath CHB2 and a substrate array passing position corresponding to a position above the sulfuric-acid bath CHB2. The lifter LF2 holds a substrate array including vertically oriented substrates W. The lifter LF2 passes the substrate array to the substrate transport mechanism WTR at the passing position. When the lifter LF2 holding a substrate array is lowered from the passing position to the immersing position, the entire substrates W are carried below the liquid surface of the chemical liquid. When the lifter LF2 rises from the immersing position to the passing position while holding the substrate array, the entire substrates W are brought above the liquid surface of the chemical liquid. The lifter LF2 can immerse the substrate array into the batch treatment bath, all at once. At this time, the lifter LF2 is lowered from the passing position to the immersing position.

The lifter LF2 can also bring the substrate array to a mist treatment position set in the mist treatment region 30a. The mist treatment position is a position between the passing position and the immersing position in the vertical direction Z.

The third batch processing unit BPU3 has the same configuration as the second batch processing unit BPU2 described above. Therefore, a substrate array is subjected to the SPM treatment in any one of the sulfuric-acid baths CHB2 and CHB3, and are subjected to the mist treatment above such one of the sulfuric-acid baths CHB2 and CHB3. By carrying out the chemical liquid treatment in parallel using two treatment units in the manner described above, the apparatus can achieve a higher throughput.

### <6. Other Configurations in Processing Block>

Configurations of the processing block 6 other than the batch processing units BPU2 and BPU3 will now be described. Specifically, the first batch processing unit BPU1 includes the batch rinsing treatment bath ONB where the pure water is stored, and a lifter LF1 that moves a substrate array up and down between the substrate passing position and a rinsing position. The substrate passing position is a position set above the batch rinsing treatment bath ONB accessible by the substrate transport mechanism WTR, and the rinsing position is a position set inside the batch rinsing treatment bath ONB where the substrate array can be immersed in the pure water. The batch rinsing treatment bath ONB has the same configuration as the sulfuric-acid bath CHB2 described above. In other words, the batch rinsing treatment bath ONB stores the pure water and is provided with the lifter LF1. Unlike other treatment baths, the batch rinsing treatment bath ONB stores pure water, and is provided for the purpose of cleaning the chemical liquid attached to the plurality of substrates W. The batch rinsing treatment bath ONB ends the cleaning treatment, when the specific electrical resistance of the pure water inside the bath increases to a predetermined level.

As described above, the batch rinsing treatment bath ONB according to this embodiment is positioned closer to the transfer block 5 than the sulfuric-acid baths CHB2 to CHB3. With such a configuration, the mechanisms included in the transfer block 5 and the sulfuric-acid baths CHB2 to CHB3 are separated as far as possible, so that the pusher mechanism 25 and the like are not adversely affected by sulfuric acid. Furthermore, by arranging the transfer block 5 and the batch drying chamber DC close to each other, it is possible to keep the distance for transporting the substrate array for which the rinse treatment has been finished short so that the substrate array is returned immediately to the transfer block 5.

The batch drying chamber DC is at a position between the first batch processing unit BPU1 and the transfer block 5. The batch drying chamber DC has a drying chamber where a substrate array including an arrangement of vertically oriented substrates W is housed. The drying chamber includes an inert gas supply nozzle for supplying an inert gas into the chamber, and a vapor supply nozzle for supplying vapor of an organic solvent into the bath. The batch drying chamber DC first supplies the inert gas onto the substrate array supported inside the chamber, and replaces the atmosphere inside the chamber with the inert gas. The pressure inside the chamber then starts being reduced. With the pressure inside the chamber reduced, the organic solvent vapor is supplied into the chamber. The organic solvent carrying the moisture having been attached to the substrate W is discharged outside of the chamber. In the manner described above, the substrate array is dried in the batch drying chamber DC. The inert gas used herein may be nitrogen, for example, and the organic solvent may be isopropyl alcohol (IPA), for example.

The substrate array support 27, the batch drying chamber DC, and the batch processing units BPU1 to BPU3 in the substrate processing apparatus 1 are arranged along the front-back direction. That is, the substrate array support 27 is positioned on the front side, and the batch drying chamber DC is positioned on the rear side of the substrate array support 27. The batch processing units BPU1 to BPU3 are disposed further on the rear side, behind the batch drying chamber DC. In the substrate processing apparatus 1 according to this embodiment, the layout inside the apparatus is optimized so as to reduce the distance by which the substrate transport mechanism WTR moves.

### <7. Other Configurations>

A control unit included in the substrate processing apparatus 1 will now be described. The control unit 131 included in the substrate processing apparatus 1 can be found in FIG. 1. The control unit 131 is provided with a storage unit, not illustrated in FIG. 1, corresponding thereto. The control unit 131 is implemented as a central processing unit (CPU), for example. There is no limitation in a specific configuration of the control unit, and the control units may each be implemented as a single processor, or as individual processors, for example.

Examples of control related to the control unit 131 include control related to the carrier transport mechanism 11, the handling robot HTR, the HVC orientation converting unit 23, the pusher mechanism 25, the substrate transport mechanism WTR, the batch processing units BPU1 to BPU3, and the batch drying chamber DC.

Examples of the control related to the batch processing units BPU2 and BPU3 include control of the nozzle heads 33, control of the shower heads 35, control of the cover driving mechanism 37, control of the heater 54, and control of the pump 55.

In particular, the control unit 131 performs control such as control for causing the lifter LF2 to bring the substrate array in the standby state to the immersed state above the sulfuric-acid bath CHB2 and to bring the substrate array in the immersed state to the standby state again, control for causing the nozzle heads 33 to supply the mist of hydrogen peroxide to the substrate array elevated from the sulfuric acid. The control unit 131 also controls the lifter LF2 to immerse the substrates having been subjected to the treatment with the mist of hydrogen peroxide solution again in the sulfuric acid, by bringing the substrate array in the standby state into the immersed state.

The control unit 131 also controls the cover driving mechanism 37 to bring the covers 32 in the open state to the closed state before supplying the mist of hydrogen peroxide to the substrate array having been elevated from the sulfuric-acid bath.

The storage unit, not illustrated, stores therein programs, parameters, and the like that are required for the operation of the control unit 131. It is possible to provide individual storage units for various functions implemented by the control unit 131, respectively, or a single storage device may implement the storage units. A specific configuration of the storage unit is not limited to a particular configuration.

### <8. Operation of Batch Processing Unit>

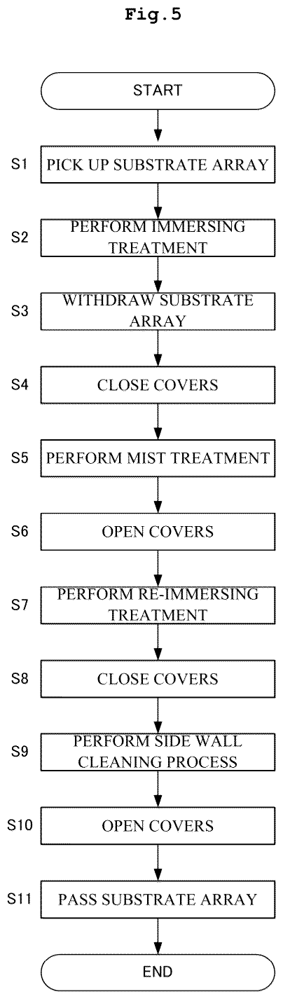

An operation of the batch processing unit will now be described with reference to drawings such as FIG. 5. Because the substrate processing apparatus 1 according to this example includes a plurality of batch processing units, the operation of the batch processing unit BPU2 will be described below as a representative example. The operations of the other batch processing units are similar to the operation of the batch processing unit BPU2.

FIG. 5 is a flowchart for explaining the operation of the batch processing unit BPU2. The flowchart includes steps S1 to S8.

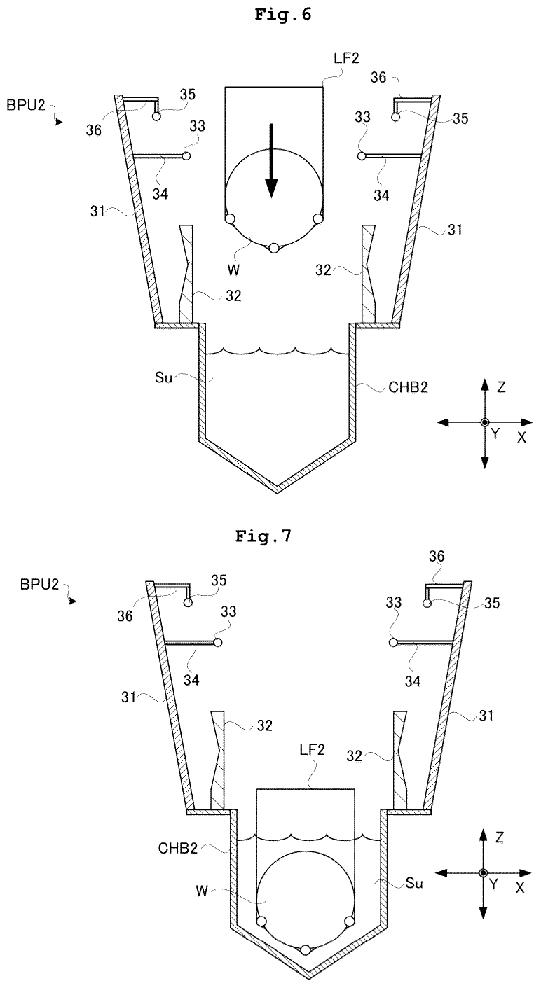

Step S1: The substrate transport mechanism WTR transports an unprocessed substrate array to the substrate passing position of the batch processing unit BPU2. The lifter LF2 picks up the substrate array from the substrate transport mechanism WTR on the spot. The lifter LF2 is then lowered, as illustrated in FIG. 6. The substrate array passes through the mist treatment region 30a, and is lowered further. At this time, the covers 32 are in the open state.

Step S2: As illustrated in FIG. 7, the lifter LF2 descends into the sulfuric-acid bath CHB2 in the immersing treatment region 30b. The substrates W included in the entire substrate array is brought under the liquid surface of the hot sulfuric acid Su. The substrate array is thus immersed. As described above, in this step, the substrate array including vertically oriented substrates that are arranged along the horizontal direction is immersed in the sulfuric acid.

Step S3: After the immersing treatment, the lifter LF2 lifts the substrate array to the mist treatment position provided in the mist treatment region 30a. The substrates W included the substrate array are entirely brought above the liquid surface of the hot sulfuric acid Su. As described above, in this step, the entire substrate array is elevated from the sulfuric acid.

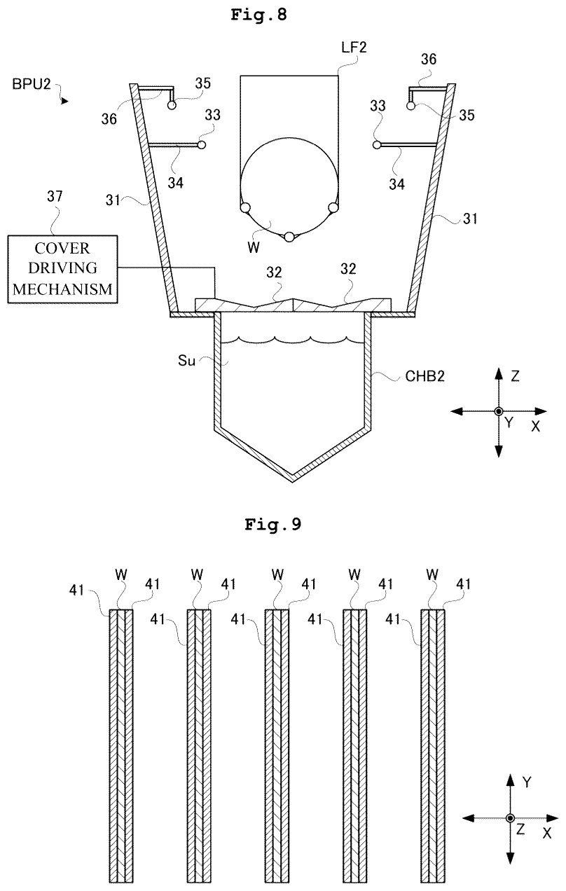

Step S4: The cover driving mechanism 37 then brings the covers 32 to the closed state, as illustrated in FIG. 8. With this, the atmosphere of the sulfuric-acid bath CHB2 can be isolated from the hydrogen peroxide.

FIG. 9 illustrates a substrate array in this step. The substrate array is positioned above the sulfuric-acid bath CHB2. Each of the substrates W in the substrate array has liquid sulfuric acid films 41 on the front surface and the rear surface, respectively.

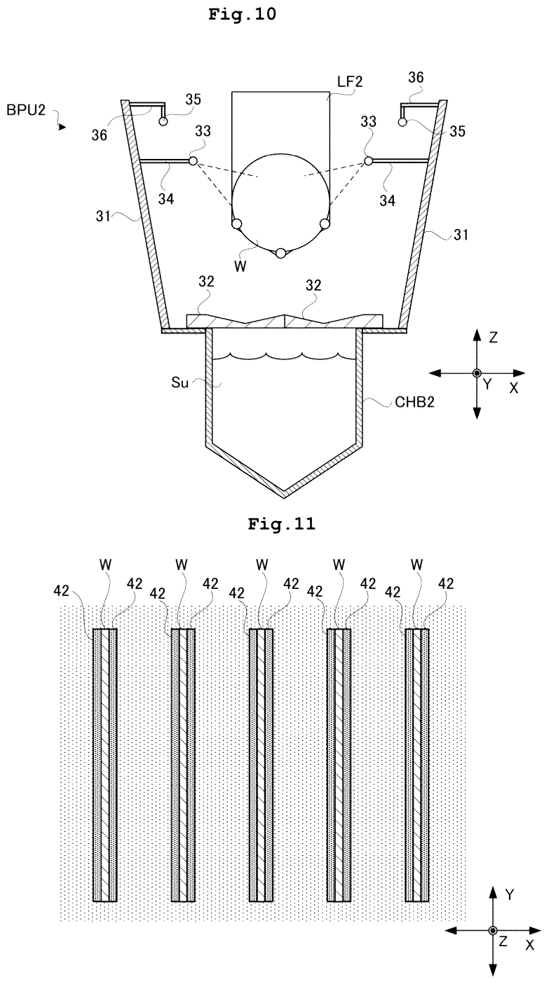

Step S5: The nozzle heads 33 then spray hydrogen peroxide solution to the substrates W, as mist, as illustrated in FIG. 10. FIG. 11 illustrates a substrate array in this step. The substrate array is positioned above the covers 32 that are in the closed state. Each of the substrates W in the substrate array is held in atmosphere containing the mist of hydrogen peroxide solution. At this time, as the hydrogen peroxide becomes added to the liquid sulfuric acid films 41, SPM films 42 are formed on the front surface and the rear surface of the substrates W. In this manner, the substrates W are subjected to the SPM treatment. According to the present invention, because the SPM is formed on a limited part of the substrate surface, only a small amount of hydrogen peroxide solution is required in the formation of SPM. As described above, with the configuration according to the present invention, a significant amount of chemical liquid used in the SPM treatment, in particular, hydrogen peroxide solution, can be saved.

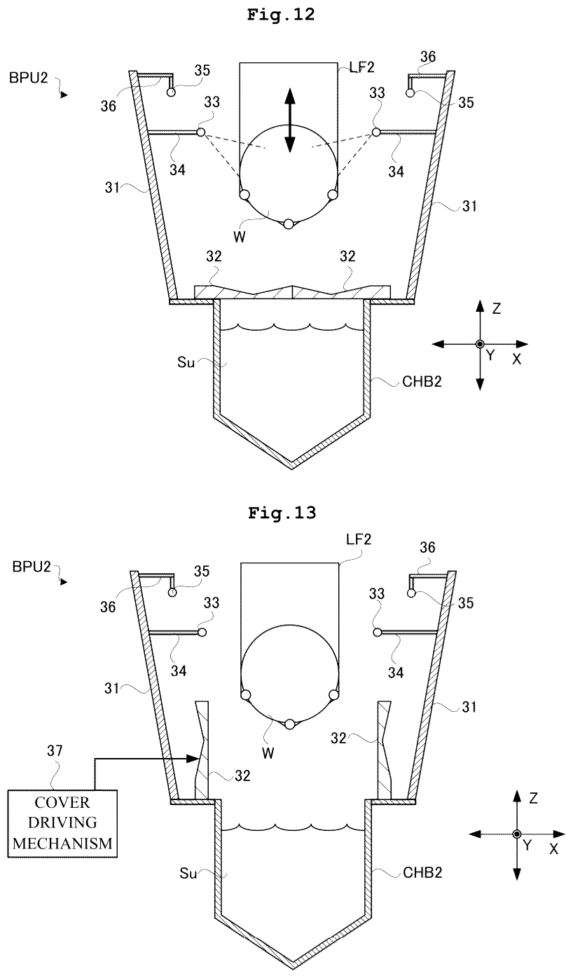

Furthermore, in this step, as illustrated in FIG. 12, the lifter LF2 moves the substrate array up and down with respect to the mist treatment position so that the entire surfaces of the substrates W included in the substrate array are subjected to the mist of hydrogen peroxide solution. In the manner described above, in this step, the mist of hydrogen peroxide is supplied to the substrate array having been elevated. In this step, the substrate array is reciprocated. With such a configuration, the substrates W are chemically treated with the SPM films 42, reliably.

Step S6: The cover driving mechanism 37 then brings the covers 32 to the open state, as illustrated in FIG. 13. The covers 32 are brought to the open state after the supply of the mist of hydrogen peroxide has ended. In this manner, the mist of hydrogen peroxide is prevented from falling onto the sulfuric-acid bath CHB2.

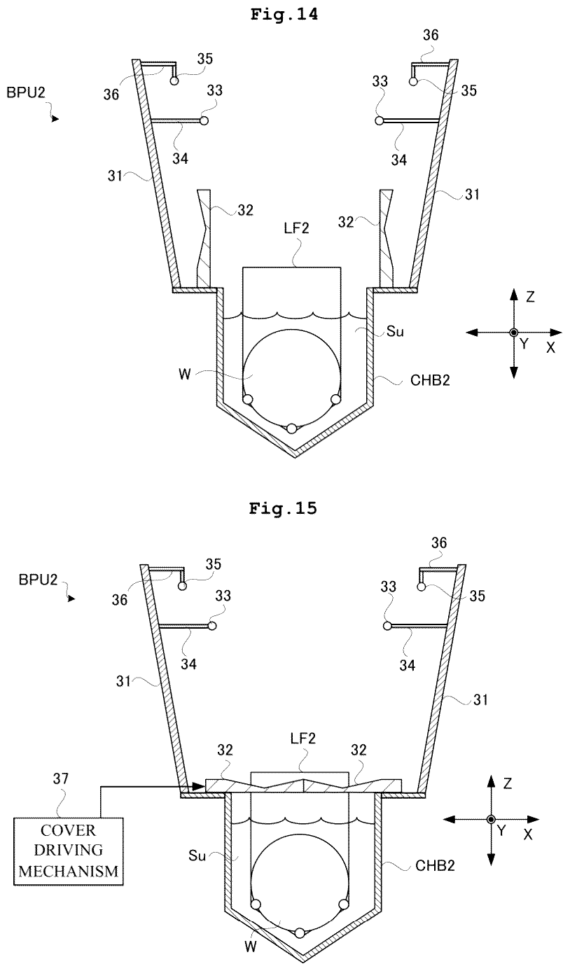

Step S7: The lifter LF2 starts descending, and eventually causes the substrate array to immerse in the sulfuric-acid bath CHB2 again, as illustrated in FIG. 14. The substrates W included in the entire substrate array is brought under the liquid surface of the hot sulfuric acid Su. The substrate array is thus subjected to re-immersing treatment. In the manner described above, in this step, after the substrate array is supplied with the mist of hydrogen peroxide solution, the substrate array is immersed in the sulfuric acid again.

Step S8: The cover driving mechanism 37 then brings the covers 32 to the closed state, as illustrated in FIG. 15. In the manner described above, the covers 32 can be in the closed state even when the lifter LF2 is at the immersing position.

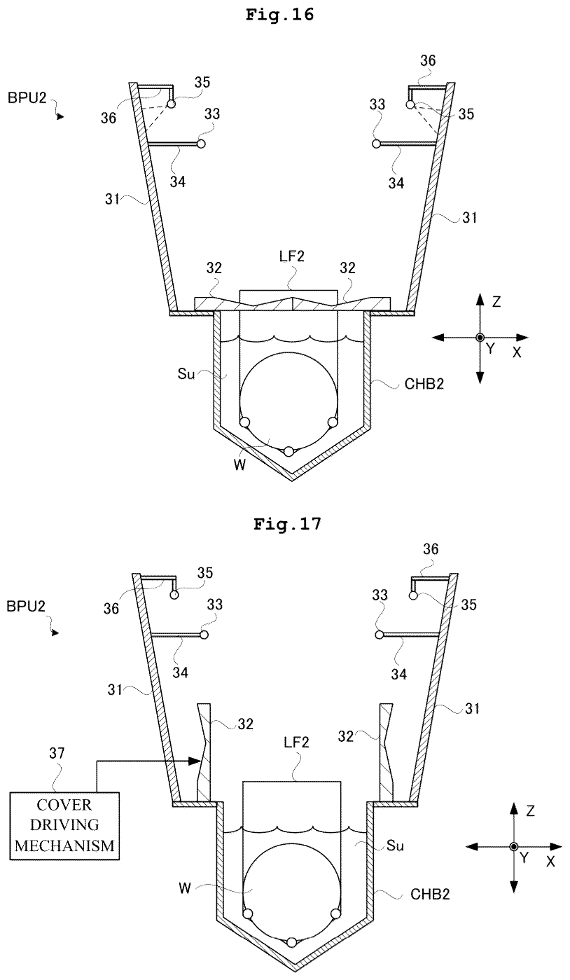

Step S9: The shower heads 35 are then caused to spray pure water, as illustrated in FIG. 16. With this, the hydrogen peroxide solution attached on the side wall 31 and the like is washed away with the pure water.

Step S10: The cover driving mechanism 37 then brings the covers 32 to the open state, as illustrated in FIG. 17.

Step S11: The lifter LF2 at the immersing position is then lifted again, so as to move the substrate array to the substrate passing position defined in the batch processing unit BPU2. The substrate array is then moved to a position where the substrate transport mechanism WTR is accessible. The substrate array on the lifter LF2 is then passed onto the substrate transport mechanism WTR. With this, the operation of the batch processing unit BPU2 according to this example is ended.

### <9. Sequence of Substrate Processing>

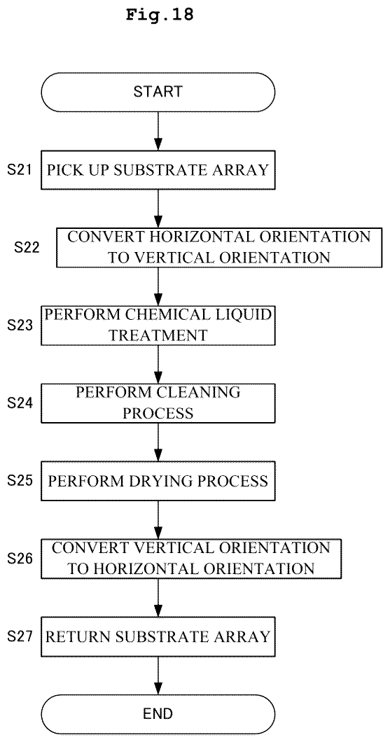

A sequence of substrate processing performed with the substrate processing apparatus according to this example will now be described. FIG. 18 is a flowchart for explaining the sequence of the substrate processing according to this example. The processing will be described in detail with reference to the drawing.

Step S21: The carrier C placed on the loading port 9 is collected to the substrate processing apparatus 1, transported by the carrier transport mechanism 11, and is placed on the carrier shelf 13a. The handling robot HTR then picks up the substrate array from the carrier C.

Step S22: The handling robot HTR passes the substrate array of horizontally oriented substrates W to the HVC orientation converting unit 23. The HVC orientation converting unit 23 converts the orientation of the substrates W in the substrate array from the horizontal orientation to the vertical orientation, by rotating the substrate array by 90°.

Step S23: The substrate array having been subjected to the orientation conversion is then transported to, for example, the batch processing unit BPU2, by the substrate transport mechanism WTR, and is subjected to the chemical liquid treatment in the batch processing unit BPU2. Specifically, this chemical liquid treatment includes immersing treatment in the sulfuric-acid bath CHB2, mist treatment with the mist of hydrogen peroxide solution, and re-immersing treatment in the sulfuric-acid bath CHB2, as described above. This step may also be performed by the batch processing unit BPU3, instead of the batch processing unit BPU2.

Step S24: The substrate array having been subjected to the chemical liquid treatment is then transported by the substrate transport mechanism WTR to the first batch processing unit BPU1, and is subjected to cleaning with pure water.

Step S25: The substrate array having been subjected to the cleaning is then transported by the substrate transport mechanism WTR to the batch drying chamber DC, and is subjected to drying.

Step S26: The substrate transport mechanism WTR then passes the substrate array of vertically oriented substrates W to the pusher mechanism 25. The HVC orientation converting unit 23 then converts the orientation of the substrates W in the substrate array from the vertical orientation to the horizontal orientation, by rotating the substrate array received from the pusher mechanism 25 by 90°.

Step S27: The handling robot HTR then returns the substrate array having been subjected to the substrate processing to an empty carrier C. The carrier transport mechanism 11 then transports the carrier C to the loading port 9. In this manner, the substrate processing according to this example comes to the end.

### <10. Effects Achieved by Configuration of Embodiment>

As described above, the substrate processing apparatus 1 according to the embodiment includes step S2 (immersing step) of immersing the substrate array of vertically oriented substrates W that are arranged along the horizontal direction in sulfuric acid, step S3 (elevating step) of elevating the entire substrate array from the sulfuric acid, and step S5 (mist supplying step) of supplying the mist of hydrogen peroxide solution to the substrate array having been elevated. With this configuration, only the liquid sulfuric acid film attached to the surface of the substrate W is turned into SPM. As a result, with the chemical treatment according to the present invention, the consumed amount of hydrogen peroxide solution is reduced significantly, compared with that consumed in a conventional counterpart.

The configuration described above further includes step S8 (re-immersing step) of re-immersing the substrate array in the sulfuric acid after step S5 (mist supplying step). With this configuration, reliability of the substrate processing applied to the substrates W is improved.

With the configuration described above, in step S5 (mist supplying step), the substrate array is reciprocated up and down in a space above a liquid surface of the sulfuric acid. With this configuration, the entire substrates can be thoroughly subjected to the hydrogen peroxide solution.

With the configuration described above, the sulfuric acid in the immersing step is set to a temperature higher than a target temperature that is suitable for removing the resist layer in the SPM treatment. With this configuration, the substrate processing in step S5 (mist supplying step) can be carried out at an appropriate temperature. In step S5 (mist supplying step), the substrates W are cooled by the mist of hydrogen peroxide solution. With this configuration, because the substrates W are heated to the higher temperature in the immersing step, by allowing the mist of hydrogen peroxide solution to cool the substrates W, the temperature of the substrates is lowered to a temperature suitable for the removal of the resist layer.

The substrate processing apparatus 1 according to the present invention includes a control unit 131 configured to control the lifter LF2 and the nozzle heads 33, and the control unit 131 controls the lifter LF2 to switch the substrate array in the standby state to the immersed state, controls the lifter LF2 to switch the substrate array in the immersed state to the standby state so that an entirety of the substrate array is elevated from sulfuric acid, and controls the nozzle heads 33 to supply the mist of hydrogen peroxide solution to the substrate array having been elevated from the sulfuric acid. With this configuration, it is possible to provide a substrate processing apparatus 1 achieving the effects according to the present invention, described above.

In the configuration described above, the lifter LF2 is controlled to switch the substrate array in the standby state to the immersed state, so that the substrates W supplied with the mist of hydrogen peroxide solution are immersed in the sulfuric acid. With this configuration, the re-immersing step described above can be implemented reliably.

The configuration described above includes: a cover 32 that is displaceable between a closed state for covering a top of the sulfuric-acid bath CHB2, and an open state for having moved to a position evacuated from above the sulfuric-acid bath CHB2; and a cover driving mechanism 37 configured to operate the cover 32, and the control unit 131 controls the cover driving mechanism 37 to switch the cover 32 in the open state to the closed state after elevating the substrate array from the sulfuric-acid bath CHB2 and before supplying the mist of hydrogen peroxide solution. With this configuration, the cover can isolate the space for the substrate processing using the sulfuric acid, from the space for the substrate processing using the hydrogen peroxide. As a result, it is possible to inhibit the mist of hydrogen peroxide solution from becoming mixed to the sulfuric acid, reliably.

The configuration described above includes a discharge port 38 for discharging the hydrogen peroxide solution having been attached to the cover 32. With this configuration, even when the cover 32 is in the open state, the hydrogen peroxide solution having been attached to the cover 32 does not reach the sulfuric-acid bath CHB2. Moreover, with this configuration, because the hydrogen peroxide solution is collected, the hydrogen peroxide solution to be sprayed as mist can be easily reused.

### <11. Modifications>

The present invention is not limited to the configurations described above, and modifications such as those described below are still possible.

### <First Modification>

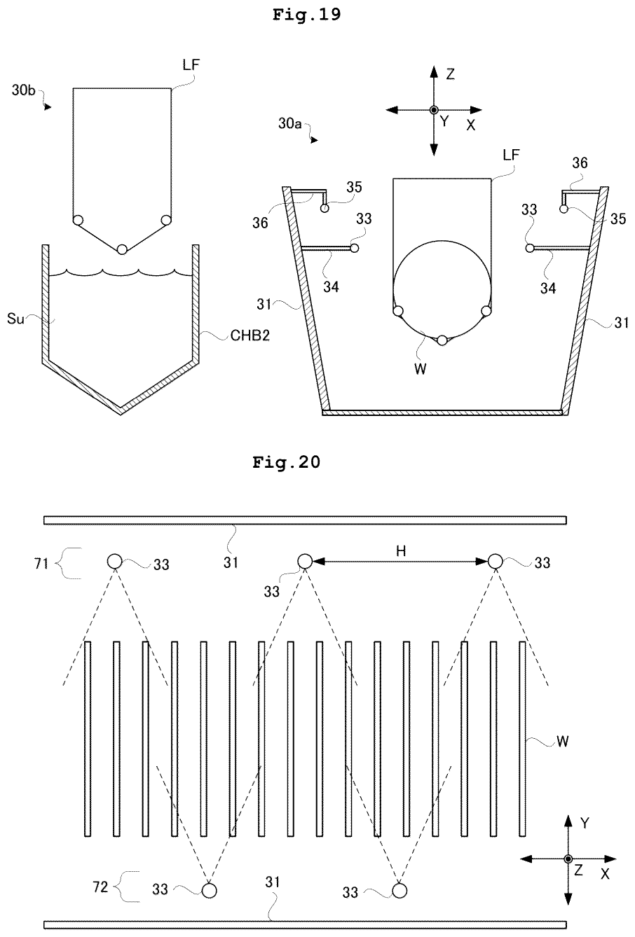

In the embodiment described above, the mist treatment region 30a and the immersing treatment region 30b are positioned along the vertical direction Z, but the present invention is not limited to such a configuration. As illustrated in FIG. 19, the mist treatment region 30a and the immersing treatment region 30b may be positioned along the horizontal direction. With this configuration, the covers 32 and the cover driving mechanism 37 can be omitted. A lifter LF is provided to each of the mist treatment region 30a and the immersing treatment region 30b. Each of the lifters LF can move the substrate array vertically from the higher position where the substrate transport mechanism WTR can pass a substrate array to a chemical liquid treatment position where the substrate array is subjected to the chemical liquid treatment. By the substrate transport mechanism WTR, the substrate array is moved between the mist treatment region 30a and the immersing treatment region 30b.

### <Second Modification>

In the embodiment described above, the mist treatment region 30a where the substrate array is treated with the mist of hydrogen peroxide solution is provided, but the present invention is not limited to such a configuration. A substrate treatment similar to that in the embodiment can be achieved using vapor of hydrogen peroxide, instead of the mist of hydrogen peroxide solution.

### <Third Modification>

In the embodiment described above, the arrangement of the nozzle heads 33 for the mist of hydrogen peroxide solution is not particularly limited, but the nozzle heads 33 may also be arranged as illustrated in FIG. 20. According to this third modification, a first nozzle head array 71 including the nozzle heads 33 at the same position in the front-back direction X and a second nozzle head array 72 at a position offset from the first nozzle head array 71 in the front-back direction X are provided. The second nozzle head array 72 includes nozzle heads 33 that are at the same position in the front-back direction X. The nozzle heads 33 included in the first nozzle head array 71 are arranged at equal intervals in the left-right direction Y. In the same manner, the nozzle heads 33 included in the second nozzle head array 72 are also arranged at equal intervals in the left-right direction Y. In the first nozzle head array 71 and the second nozzle head array 72, the distance by which the adjacent nozzle heads 33 in the left-right direction Y are separated from each other is a predetermined distance H, and is unified. The nozzle heads 33 included in the second nozzle head array 72 are provided at positions offset in the left-right direction Y by a half the predetermined distance H with respect to the nozzle heads 33 included in the first nozzle head array 71.

That is, provided in this modification are: a first nozzle head array 71 including a plurality of the nozzle heads 33 that are arranged along a direction in which the substrates W in the substrate array are arranged, with a predetermined distance H between the nozzle heads 33; and a second nozzle head array 72 including a plurality of the nozzle heads 33 that are arranged along the direction in which the substrates W in the substrate array are arranged, with a predetermined distance H between the nozzle heads 33, with the substrate array being interposed between the first nozzle head array 71 and the second nozzle head array 72 in a direction orthogonal to the direction in which the substrates are arranged, and the nozzle heads 33 included in the second nozzle head array 72 are provided at positions offset from the respective nozzle heads 33 included in the first nozzle head array 71, by a half the predetermined distance H in the direction in which the substrates W are arranged. With this configuration, the mist of hydrogen peroxide solution can be evenly supplied to the substrate array.

### <Fourth Modification>

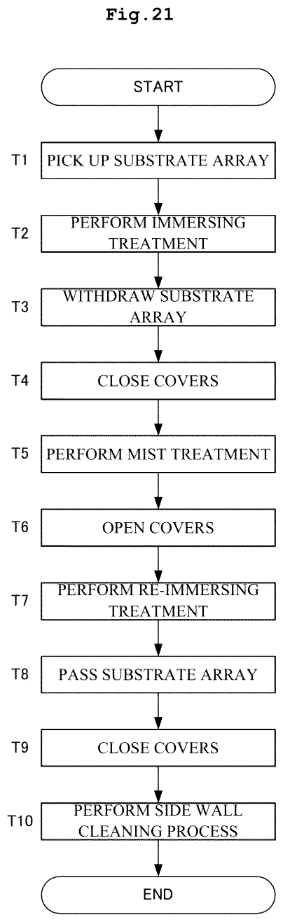

The operation of the batch processing unit in the embodiment described above is one example. A step of cleaning the side wall may be performed, after the substrates are passed, as indicated in the flowchart in FIG. 21. That is, steps T1 to T7 in FIG. 21 correspond to steps S1 to S7 in the embodiment, respectively. The operation of the batch processing unit in this modification is the same as the operation according to the embodiment described with reference to FIG. 5, up to the process of re-immersing the substrate W in the sulfuric-acid bath CHB2. The operation according to this modification after step T8 will now be described with reference to FIG. 21.

Step T8: The lifter LF2 at the immersing position is then lifted again, so as to move the substrate array to the substrate passing position defined in the batch processing unit BPU2. The substrate array is then moved to a position where the substrate transport mechanism WTR is accessible. The substrate array on the lifter LF2 is then passed onto the substrate transport mechanism WTR.

Step T9: The cover driving mechanism 37 then brings the covers 32 to the closed state, as illustrated in FIG. 15.

Step T10: Pure water is then sprayed out of the shower heads 35. With this, the hydrogen peroxide solution attached on the side wall 31 and the like is washed away with the pure water. At this time, because the covers 32 are in the closed state, the sprayed pure water does not fall on the sulfuric-acid bath CHB2. With this, the operation of the batch processing unit BPU2 according to this modification is ended.

What is claimed is:

1. A substrate processing method comprising:
an immersing step of immersing a substrate array that is a horizontal arrangement of vertically oriented substrates in sulfuric acid;
a elevating step of elevating an entirety of the substrate array from the sulfuric acid; and
a mist supplying step of supplying mist of hydrogen peroxide solution to the substrate array having been elevated.

2. The substrate processing method according to claim 1, further comprising a re-immersing step of re-immersing the substrate array in the sulfuric acid, after the mist supplying step.

3. The substrate processing method according to claim 1, wherein in the mist supplying step, the substrate array is reciprocated up and down in a space above a liquid surface of the sulfuric acid.

4. The substrate processing method according to claim 1, wherein
the substrate array has a resist layer, and
the sulfuric acid in the immersing step is set to a temperature higher than a target temperature that is suitable for removing the resist layer.

5. A substrate processing apparatus comprising:
a sulfuric-acid bath capable of holding sulfuric acid;
a lifter holds a substrate array that is a horizontal arrangement of vertically oriented substrates, and is capable of switching the substrate array between a standby state in which the substrate array is positioned above a liquid surface of the sulfuric-acid bath and an immersed state in which the substrate array is positioned below the liquid surface;
a mist feeding unit configured to supply mist of hydrogen peroxide solution to the substrate array; and
a control unit configured to control the lifter and the mist feeding unit,
wherein the control unit
controls the lifter to switch the substrate array in the standby state to the immersed state,
controls the lifter to switch the substrate array in the immersed state to the standby state so that an entirety of the substrate array is elevated from sulfuric acid, and
controls the mist feeding unit to supply the mist of hydrogen peroxide solution to the substrate array having been elevated from the sulfuric acid.

6. The substrate processing apparatus according to claim 5, wherein the control unit controls the lifter to switch the substrate array in the standby state to the immersed state so that the substrates supplied with the mist of hydrogen peroxide solution are immersed in the sulfuric acid.

7. The substrate processing apparatus according to claim 5, wherein
the mist feeding unit includes a nozzle head provided at a tip of a nozzle for supplying the hydrogen peroxide solution,
the substrate processing apparatus comprises
a first nozzle head array including a plurality of the nozzle heads that are arranged along a direction in which the substrates are arranged, with a predetermined distance between the nozzle heads, and
a second nozzle head array including a plurality of the nozzle heads that are arranged along the direction in which the substrates are arranged, with a predetermined distance between the nozzle heads, with the substrate array being interposed between the first nozzle head array and the second nozzle head array in a direction orthogonal to the direction in which the substrates are arranged, and
the nozzle heads included in the second nozzle head array are provided at positions offset from the respective nozzle heads included in the first nozzle head array, by a half the predetermined distance in the direction in which the substrates are arranged.

8. The substrate processing apparatus according to claim 5, further comprising:
a cover that is displaceable between a closed state for covering a top of the sulfuric-acid bath, and an open state for having moved to a position evacuated from above the sulfuric-acid bath; and
a cover driving mechanism configured to operate the cover,
wherein the control unit controls the cover driving mechanism to switch the cover in the open state to the closed state after elevating the substrate array from the sulfuric-acid bath and before supplying the mist of hydrogen peroxide solution.

9. The substrate processing apparatus according to claim 8, further comprising a discharge port for discharging the hydrogen peroxide solution having been attached to the cover.
